(19) United States
(12) Patent Application Publication
(10) Pub. No.: US 2024/0114705 A1
(43) Pub. Date: Apr. 4, 2024

(54) PHASE CHANGE MATERIAL SWITCH FOR LOW POWER CONSUMPTION AND METHODS FOR FORMING THE SAME

(71) Applicant: Taiwan Semiconductor Manufacturing Company Limited, Hsinchu (TW)

(72) Inventors: Hiroki Noguchi, Hsinchu City (TW); Yih Wang, Hsinchu City (TW)

(21) Appl. No.: 18/310,556

(22) Filed: May 2, 2023

Related U.S. Application Data
(60) Provisional application No. 63/412,841, filed on Oct. 3, 2022.

(51) Int. Cl. H10B 80/00; H01L 25/00; H01L 25/065; H01L 25/18

(52) U.S. Cl. CPC H10B 80/00; H01L 25/0657; H01L 25/18; H01L 25/50; H01L 2225/06513; H01L 2225/06541

(57) ABSTRACT

A chip assembly structure includes a first chip-containing structure and a second chip-containing structure. The first chip-containing structure includes a back-end-of-line (BEOL) memory die including an array of memory cells and metal interconnect structures. The BEOL memory die is free of any semiconductor material portion having a greater a lateral extent greater than a lateral extent of each memory cell. The first chip-containing structure includes first bonding structures, and a subset of the first bonding structures is electrically connected to the metal interconnect structures in the BEOL memory die. The second chip-containing structure includes a control circuit including field effect transistors which are configured to control operation of the array of memory cells and further includes second bonding structures. The second bonding structures are bonded to the first bonding structures through metal-to-metal bonding or through-substrate-via-mediated bonding.

### RELATED APPLICATIONS

This application claims priority to U.S. Provisional Patent Application No. 63/412,841, entitled “Memory Integration with Separated BEOL Memory Die and Peripheral Circuit Die” filed on Oct. 3, 2022, the entire contents of which are incorporated herein by reference.

### BACKGROUND

A memory array requires a control circuit that controls operation of memory cells within the memory array. The control circuit requires field effect transistors formed on a semiconductor substrate. Thus, a control circuit is formed on a semiconductor substrate, and a memory array is formed within back-end-of-line (BEOL) structures that overlie the control circuit. Such an approach results in a device in which a memory array and a control circuit are integrated within a same semiconductor die.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of a chip assembly structure including a first chip-containing structure and a second chip-containing structure according to an embodiment of the present disclosure.

FIG. 2A illustrates a first configuration of the chip assembly structure according to an embodiment of the present disclosure.

FIG. 2B illustrates a second configuration of the chip assembly structure according to an embodiment of the present disclosure.

FIG. 3A is a perspective view of an assembly of a first chip-containing structure and a second chip-containing structure that contains a single die-to-die connection region according to an embodiment of the present disclosure.

FIG. 3B is a perspective view of an assembly of a first chip-containing structure and a second chip-containing structure that contains two die-to-die connection regions according to an embodiment of the present disclosure.

FIG. 3C is a schematic top-down view of a region of the first chip-containing structure of FIG. 3B.

FIG. 3D is perspective view of components electrically connected to a memory cell in an assembly of a first chip-containing structure and a second chip-containing structure in an embodiment in which the memory cell is a three-terminal device connected to a word line and two bit lines.

FIG. 3E is a schematic vertical cross-sectional view of the bonded assembly of FIG. 3D.

FIG. 4 is an exemplary layout for through-substrate via structures that may be used for the chip assembly structure according to an embodiment of the present disclosure.

FIG. 5 is an exemplary layout for bonding pad arrays that may be used for hybrid bonding for the chip assembly structure according to an embodiment of the present disclosure.

FIGS. 6A-6F illustrate various configurations for the first chip-containing structure in embodiments in which the first chip-containing structure comprises a redistribution structure according to an embodiment of the present disclosure.

FIGS. 7A-7G illustrate various configurations for the first chip-containing structure in embodiments in which the first chip-containing structure comprises an interposer according to an embodiment of the present disclosure.

FIGS. 8A and 8B illustrate various configurations for the first chip-containing structure in embodiments in which the first chip-containing structure comprises a chip assembly that is free of redistribution structures and interposers according to an embodiment of the present disclosure.

FIG. 9 is a schematic vertical cross-sectional view of a memory-containing die and a peripheral die that may be used for the chip assembly structure according to an embodiment of the present disclosure.

FIG. 10A is a schematic vertical cross-sectional view of a chip assembly structure including two memory-containing dies and a peripheral die according to an embodiment of the present disclosure.

FIG. 10B is a schematic vertical cross-sectional view of a chip assembly structure including a memory-containing die and a peripheral die according to an embodiment of the present disclosure.

FIG. 10C is a schematic vertical cross-sectional view of another chip assembly structure including a memory-containing die and a peripheral die according to an embodiment of the present disclosure.

FIG. 11 illustrates formation of backside through-substrate via structures on a backside of the peripheral die that may be used for the chip assembly structure of the present disclosure.

FIG. 12 is a flowchart that illustrates general processing steps for manufacturing the chip assembly structure according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Elements with the same reference numerals refer to the same element, and are presumed to have the same material composition and the same thickness range unless expressly indicated otherwise.

Generally, the various embodiment structures and methods disclosed herein may be used to form a chip assembly structure in which a memory array and a peripheral circuit controlling operation of the memory array may be implemented in different semiconductor dies. The memory array may be implemented in a back-end-of-line (BEOL) memory die that is free of any front-end-of-line device components such as a semiconductor substrate. The peripheral circuit may be implemented in a front-end-of-line (FEOL) device die that includes a semiconductor substrate. A first chip-containing structure including the BEOL memory die is prepared, and a second chip-containing structure including the FEOL device die is provided. The first chip-containing structure and the second chip-containing structure may be integrated into a chip assembly structure using die-to-die (D2D) connection. In some embodiments, the first chip-containing structure may comprise at least one additional BEOL memory die, at least one logic die, a redistribution structure, and/or an interposer structure.

Since the memory array and the peripheral circuit may be provided in different semiconductor dies, the set of processing steps for manufacturing the BEOL memory die and the set of processing steps for manufacturing the FEOL device die may be selected independently, i.e., without regard to the impact on device performance of the other set of processing steps used to form the other semiconductor die. Thus, the set of processing steps for manufacturing the BEOL memory die may be optimized without any regard to the set of processing steps for manufacturing the FEOL device die, and vice versa. This provides independent optimization of the BEOL memory die and the FEOL device die. For example, the BEOL memory die may be optimized with a focus on the density of the memory cells, and the FEOL device die may be optimized with a focus on the device speed, reduction of the process variability, and reliability of semiconductor devices during operation (including, but not limited to, reliability of the device with respective to power supply voltage variation). Further, separate manufacture and optimization of the BEOL memory die and the FEOL device die may provide a low-cost high-performance chip assembly structure. The various embodiments of the present disclosure are now described with reference to accompanying drawings.

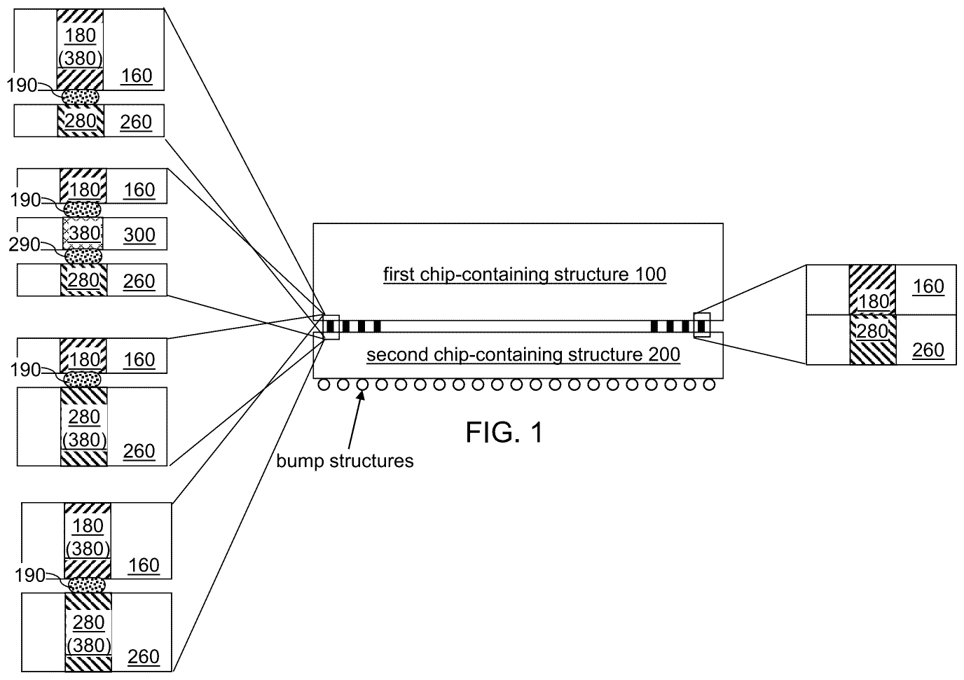

Referring to FIG. 1, a chip assembly structure including a first chip-containing structure 100 and a second chip-containing structure 200 is illustrated according to an embodiment of the present disclosure. The first chip-containing structure 100 comprises a back-end-of-line (BEOL) memory die (not expressly shown) including an array of memory cells and metal interconnect structures that are electrically connected to a respective node of the memory cells. The first chip-containing structure 100 may consist of the BEOL memory die, or may comprise at least one additional component such as at least one additional BEOL memory die, at least one logic die, at least one redistribution structure, and/or at least one interposer such as at least one organic interposer.

As used herein, a “back-end-of-line component” or a “BEOL component” refers to any component that is formed at a contact level or at a metal interconnect level. A “metal interconnect level” refers to a level through which a metal interconnect structure, such as a metal line or a metal via structure, vertically extends. As used herein, a “front-end-of-line component” or an “FEOL component” refers to any component that is formed prior to formation of any contact level structure, if followed by formation of contact level structures, or without formation of any contact level structure or any metal interconnect structure (i.e., not followed by formation of any contact level structure or any metal interconnect structure).

Customarily, FEOL components refer to semiconductor device components that may be formed during a CMOS manufacturing process prior to formation of any contact via structure on nodes of field effect transistors, and BEOL components refer to semiconductor device components that may be formed during a CMOS manufacturing process during, or after, the earliest contact via formation process that forms contact via structures on nodes of field effect transistors. In embodiments in which any unconventional manufacturing steps are integrated into a CMOS manufacturing process, a component formed prior to formation of any contact via structure on nodes of field effect transistors is an FEOL component; and a component formed during, or after, the earliest contact via formation process that forms contact via structures on nodes of field effect transistors is a BEOL component.

Generally, an FEOL component may be formed within a semiconductor substrate, directly on a semiconductor substrate, or indirectly on a semiconductor substrate without any intervening metal interconnect structure between the semiconductor substrate and the component. Examples of the FEOL components include planar field effect transistors using a portion of the semiconductor substrate as a portion of a channel, fin field effect transistors, gate-all-around field effect transistors, and any device component that includes a portion of a semiconductor substrate that has a lateral extent greater than the lateral extent of the respective device component. Typically, for each FEOL component, no metal interconnect structure vertically extends from a first horizontal plane including a top surface of the FEOL component to a second horizontal plane including a bottom surface of the FEOL component, or the FEOL component contacts, or is laterally surrounded by, a semiconductor material layer having a greater lateral extent than the FEOL component.

Any component formed during, or after, formation of an earliest contact via structure is a BEOL component. Examples of the BEOL components include any dielectric material layer embedding a metal via structure or embedding a metal line structure, any metal interconnect structure, memory cells formed without using any portion of a semiconductor substrate, selector cells formed without using any portion of a semiconductor substrate, thin film transistors formed without using any portion of a semiconductor substrate (but may include patterned semiconductor material portions having a lateral extent that does not exceed the lateral extent of an individual thin film transistor or a cluster of merged thin film transistors), and bonding pads. Typically, for each BEOL component, at least one metal interconnect structure vertically extends from a first horizontal plane including a top surface of the BEOL component to a second horizontal plane including a bottom surface of the BEOL component, and the BEOL component does not contact, and is not laterally surrounded by, a semiconductor material layer having a greater lateral extent than the BEOL component.

As used herein a “back-end-of-line memory die” or a “BEOL memory die” refers to a die that include a memory array and including back-end-of-line components and not including front-end-of-line components. In other words, a BEOL memory die is free of any FEOL component, and includes a memory array and BEOL components. As a corollary, a BEOL memory die is free of any semiconductor material portion, or, in embodiments in which any semiconductor material portion is present within the BEOL memory die, each semiconductor material portions within the BEOL memory die has a lateral extent that is less than the lateral extent of each memory cell within the array of memory cells. In other words, in embodiments in which any semiconductor material portion is present within a BEOL memory die, each such semiconductor material portion has a lesser lateral extent than the lateral extent of any single memory cell within the BEOL memory die. The lateral extent of each memory cell within a BEOL memory die may be calculated by the pitches (periodicities) of the BEOL memory die, and is the greater of the two two-dimensional pitches of the memory cells along two different horizontal directions, or in the embodiment in which of a one-dimensional array, the one-dimensional pitch.

The first chip-containing structure 100 comprises first bonding structures 180. At least a subset of the first bonding structures 180 is electrically connected to the metal interconnect structures in the BEOL memory die. In one embodiment, the first bonding structures 180 may be laterally surrounded by a first bonding-level dielectric layer 160, which may comprise a dielectric material that may provide dielectric-to-dielectric bonding (such as silicon oxide), or may comprise a passivation dielectric material (such as silicon nitride or silicon carbide nitride).

According to an aspect of the present disclosure, a second chip-containing structure 200 is provided. The second chip-containing structure 200 may comprise a control-circuit-containing die which comprises a control circuit including field effect transistors which are configured to control operation of the array of memory cells in the BEOL memory die. Further, the second-chip-containing structure 200 comprises second bonding structures 280 that are configured to provide die-to-die bonding with the first bonding structures 180 in the first chip-containing structure 100.

According to an aspect of the present disclosure, the die-to-die bonding used between the first chip-containing structure 100 and the second chip-containing structure may use metal-to-metal bonding or through-substrate-via-mediated bonding.

As used herein, a “metal-to-metal bonding” refers to a bonding method and a bonded structure in which bonded structures are formed by direct contact between a first metal surface and a second metal surface and interdiffusion of metal atoms across a bonding interface between the first metal surface and the second metal surface. An exemplary metal-to-metal bonding is copper-to-copper bonding. In embodiments in which the die-to-die bonding uses metal-to-metal bonding, the first bonding structures 180 (such as first copper bonding pads) are directly bonded to the second bonding structures 280 (such as second copper bonding pads).

In one embodiment, dielectric bonding between mating pairs of dielectric material layers may be used in conjunction with metal-to-metal bonding. This type of bonding is herein referred to as hybrid bonding. Generally, hybrid bonding uses metal-to-metal bonding and dielectric-to-dielectric bonding. In embodiments in which hybrid bonding is used, the first bonding structures 180 may be embedded within a first bonding-level dielectric layer 160 and the second bonding structures 280 may be embedded with a second bonding-level dielectric layer 260. The first bonding-level dielectric layer 160 may be bonded to the second bonding-level dielectric layer 260 by dielectric-to-dielectric bonding such as silicon oxide-to-silicon oxide bonding.

As used herein, a “through-substrate-via-mediated bonding” refers to a bonding method or a bonding structure in which an array of through-substrate via structures vertically extending through an embedding matrix material is used to provide bonding between a first die and a second die such that an array of solder material portions provides bonding between bonding pads in the first die and the array of through-substrate via structures. In one embodiment, the array of through-substrate via structures may be embedded with a substrate (which may be a semiconductor substrate or a dielectric substrate), and may be attached to the second die through an additional array of solder material portions that are bonded to a respective pair of a through-substrate via structure and a bonding pad in the second die. Alternatively, the array of through-substrate via structures may be located within the second semiconductor die.

In an illustrative example, a substrate 300 including an array of through-substrate via (TSV) structures 380 may be provided, a first array of solder material portions 190 may be used to attach the first bonding structures 180 to the array of TSV structures 380, and a second array of solder material portions 290 may be used to attach the second bonding structures 280 to the array of TSV structures 380. In another illustrative example, the array of TSV structures 380 may comprise the first bonding structures 180. In other words, the first bonding structures 180 may be formed as the array of TSV structures 380. In this embodiment, an array of solder material portions 190 may be used to provide bonding between the first bonding structures 180 (which are the TSV structures 380) and the second bonding structures 280. In yet another illustrative example, the array of TSV structures 380 may comprise the second bonding structures 280. In other words, the second bonding structures 280 may be formed as the array of TSV structures 380. In this embodiment, an array of solder material portions 190 may be used to provide bonding between the first bonding structures 180 and the second bonding structures 280 (which are the TSV structures 380).

Generally, the electrical nodes of the BEOL memory die may be connected to electrical nodes of the control-circuit-containing die through an array of TSV structures 380 or through metal-to-metal bonding between mating pairs of bonding structures (180, 280). The electrical connections may be provided for all bit lines and for all word lines in the memory array within the BEOL memory die. The control-circuit-containing die may comprise the entirety of the control circuit for the BEOL memory die. For example, the control-circuit-containing die may comprise all peripheral circuits including, but not limited to, bit line drivers, word line drivers, sense amplifiers, design-for-testability (DFT) circuits, scan chain circuits, built-in-self-test (BIST) circuits, error correction circuits (ECCs), phase-locked loop (PLL) circuits, electrically-programmable fuse (e-Fuse) circuits, input/output (IO) circuits, voltage generator (power supply) circuits, etc.

Generally, the front side (i.e., the top side) or the backside (i.e., the bottom side) of the first chip-containing structure 100 may be used to form the first bonding structures 180. Likewise, the front side (i.e., the top side) or the backside (i.e., the bottom side) of the second chip-containing structure 200 may be used to form the second bonding structures 280. As such, front-to-front bonding, front-to-back bonding, back-to-front bonding, or back-to-back bonding may be used to bond the second chip-containing structure 200 to the first chip-containing structure 100. Further, as will be elaborated below, at least one additional structure may be integrated into the first chip-containing structure 100 in addition to the BEOL memory die, which may comprise at least one additional BEOL memory die, at least one logic die, a redistribution structure, and/or an interposer structure.

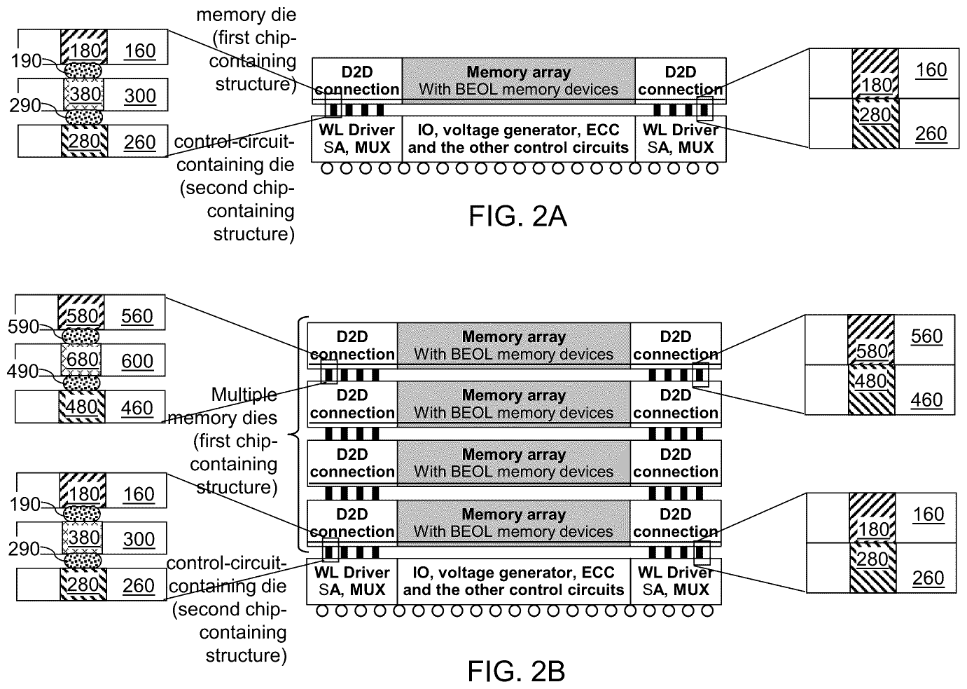

Referring to FIG. 2A, a first configuration of the chip assembly structure according to an embodiment of the present disclosure is illustrated. In the first configuration, the first chip-containing structure 100 consists of a single BEOL memory die. The single BEOL memory die comprises a memory array, such as a two-dimensional memory array or a three-dimensional memory array formed within dielectric material layers. Die-to-die connection interconnect structures (comprising the first bonding structures 180 that are embedded within first bonding-level dielectric material layers 160) may be formed within the BEOL memory die. The die-to-die interconnect structures are also referred to as “D2D connections.” The first bonding structures 180 may be provided in any configuration discussed with reference to FIG. 1. The first bonding structures 180 may be used to bond the BEOL memory die to a peripheral die through second bonding structures 280 in a manner consistent with the description of FIG. 1.

Referring to FIG. 2B, a second configuration of the chip assembly structure according to an embodiment of the present disclosure. In the second configuration, the first chip-containing structure 100 comprises multiple BEOL memory dies that are vertically stacked and interconnected to one another. Each of the multiple BEOL memory dies comprises a respective memory array, such as a two-dimensional memory array or a three-dimensional memory array formed within a respective set of dielectric material layers. The bottommost BEOL memory die comprises die-to-die connection interconnect structures (comprising the first bonding structures 180 that are embedded within first bonding-level dielectric material layers 160). The first bonding structures 180 may be provided in any configuration discussed with reference to FIG. 1. Each vertically neighboring pair of BEOL memory dies may be interconnected to each other through additional die-to-die connection structures.

For example, a first BEOL memory die within each vertically-neighboring pair of BEOL memory dies may comprise third bonding structures 480 that are embedded in a third bonding-level dielectric layer 460, and the second BEOL memory die within each vertically-neighboring pair of BEOL memory dies may comprise fourth bonding structures 580 that are embedded in a fourth bonding-level dielectric layer 560. The third bonding structures 480 may be bonded to the fourth bonding structures 580 through metal-to-metal bonding or through-substrate-via-mediated bonding. In one embodiment, the third bonding structures 480 may be bonded to the fourth bonding structures 580 through metal-to-metal bonding, and the third bonding-level dielectric layer 460 may be bonded to the fourth bonding-level dielectric layer 560 through dielectric bonding. In one embodiment, one, a plurality, or each, of the vertically neighboring pairs of BEOL memory dies may be bonded via hybrid bonding.

Alternatively, or additionally, one, a plurality, or each, of the vertically neighboring pairs of BEOL memory dies may be bonded via through-sub state-via-mediated bonding. For example, a substrate 600 including an array of through-substrate via (TSV) structures 680 may be provided, a third array of solder material portions 490 may be used to attach the third bonding structures 480 to the array of TSV structures 680, and a fourth array of solder material portions 590 may be used to attach the fourth bonding structures 580 to the array of TSV structures 680. In another illustrative example, the array of TSV structures 680 may comprise the third bonding structures 480. In other words, the third bonding structures 480 may be formed as the array of TSV structures 680. In this embodiment, an array of solder material portions 490 may be used to provide bonding between the third bonding structures 480 (which are the TSV structures 680) and the fourth bonding structures 580. In yet another illustrative example, the array of TSV structures 680 may comprise the fourth bonding structures 580. In other words, the fourth bonding structures 580 may be formed as the array of TSV structures 680. In this embodiment, an array of solder material portions 490 may be used to provide bonding between the third bonding structures 480 and the fourth bonding structures 580 (which are the TSV structures 680).

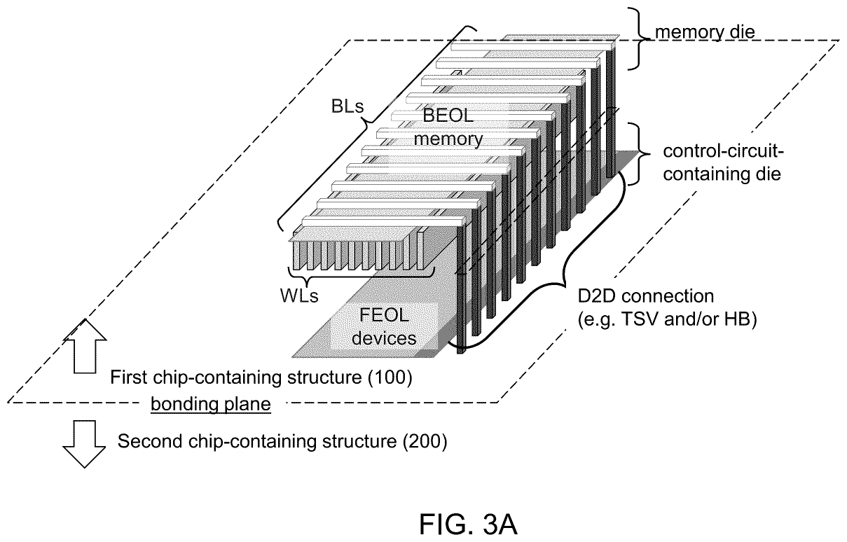

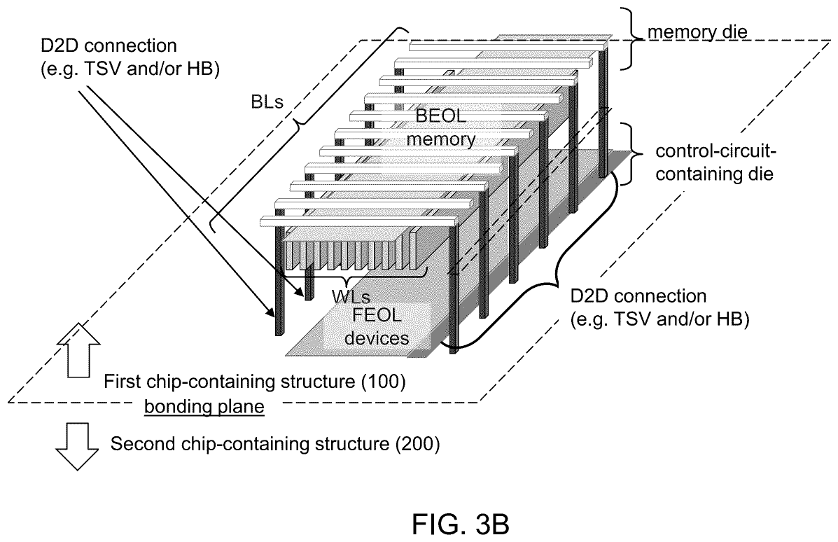

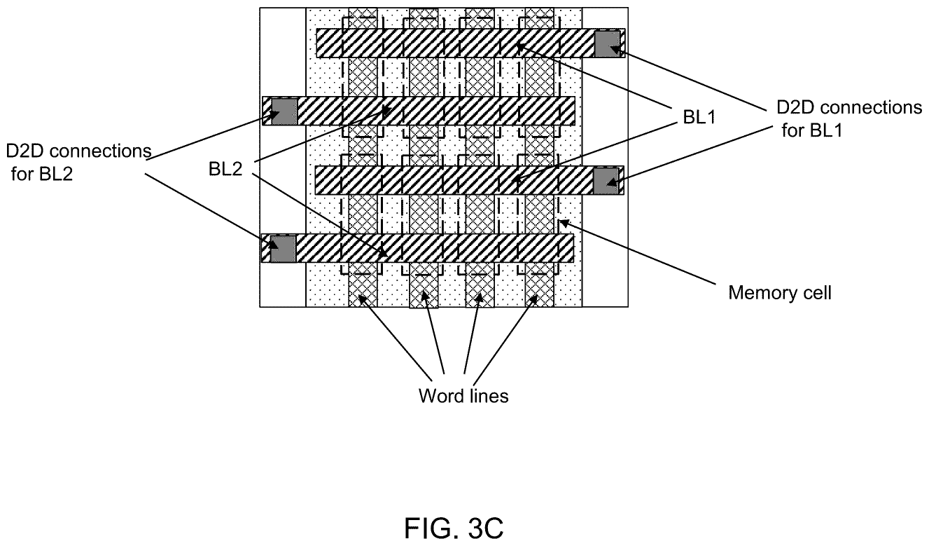

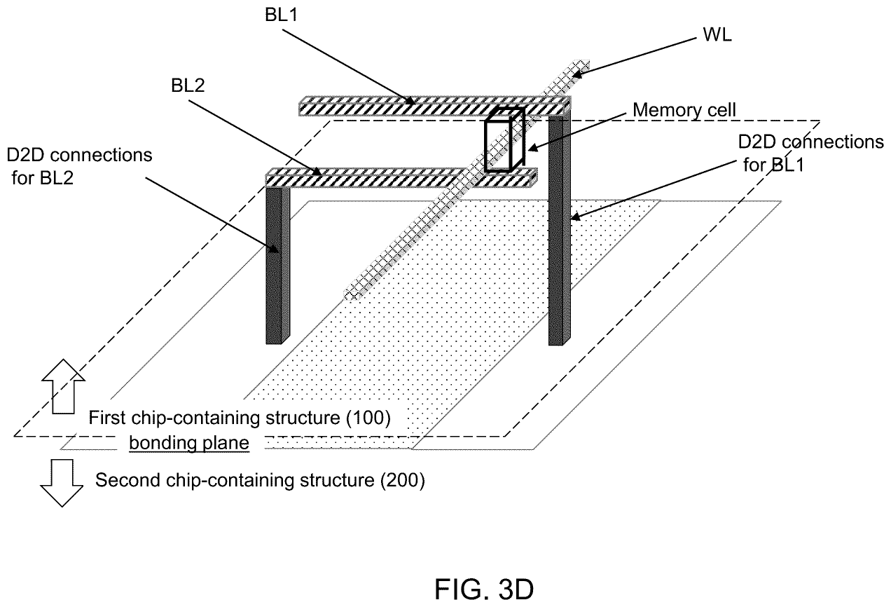

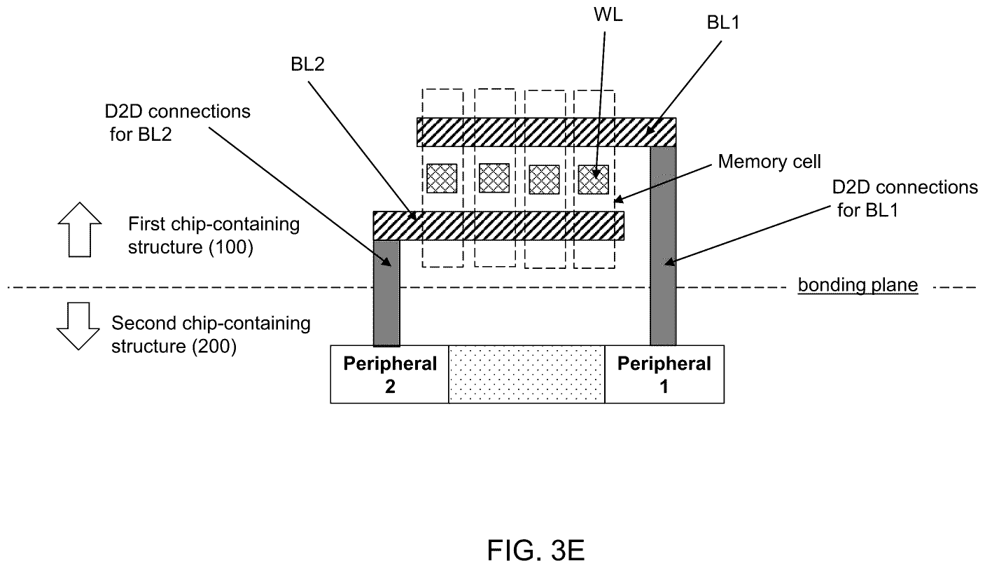

Referring to FIG. 3A, a region around bonding interfaces between a first chip-containing structure and a second chip-containing structure is illustrated in a perspective view. Die-to-die connection structures, such as through-substrate via structures or hybrid bonding structures, may be used to provide electrically conductive paths between the first chip-containing structure and the second chip-containing structure. The first chip-containing structure comprises a BEOL memory die, and may optionally comprise at least one additional BEOL memory die, at least one logic die, a redistribution structure, and/or an interposer structure. The second chip-containing structure comprises a control-circuit-containing die that includes a control circuit for each memory array within the at least one BEOL memory die. The die-to-die connection structures may provide electrical connection for each component of the control circuit, such as a word line driver, a sense amplifier, etc. The control-circuit-containing die may comprise miscellaneous peripheral circuits that are not directly related to operation of the memory array(s) in the at least one BEOL memory die. For example, the miscellaneous peripheral circuits may comprise a high-voltage circuit and/or an analog circuit. In some embodiment, the control circuit in the control-circuit-containing die may be configured to control each of the memory arrays located within a stack of multiple BEOL memory dies. In this embodiment, the total die area of the control-circuit-containing die may be reduced by sharing the control circuit with multiple memory arrays.

The first chip-containing structure may comprise a two-dimensional array of memory elements. In embodiments in which the memory elements are two-terminal memory devices, word lines (WL's) and bit lines (BL's) may be used to access each of the two-terminal memory devices. Die-to-die connection structures for the bit lines are expressly illustrated in FIG. 3A, while die-to-die connection structures for the word lines are not expressly illustrated, although such die-to-die connection structures for the word lines are present in the bonded assembly and provide electrical connection between the two chip-containing bonding structures. Generally, the layout for the first bonding structures 180 and the second bonding structures 280 may be optimized as needed.

Referring to FIGS. 3B and 3C, a portion of a bonded assembly is illustrated in an embodiment in which the first chip-containing structure may comprise a two-dimensional array of memory elements, and the memory elements are three-terminal memory devices. In this embodiment, word lines (WL's), first bit lines (BL1's), and second bit lines (BL2's) may be used to access each of the three-terminal memory devices. In the illustrated configuration, the first bit lines and the second bit lines may be formed at the same level. Die-to-die connection structures for the first bit lines and die-to-die connection structures for the second bit lines are expressly illustrated in FIGS. 3B and 3C, while die-to-die connection structures for the word lines are not expressly illustrated, although such die-to-die connection structures for the word lines are present in the bonded assembly and provide electrical connection between the two chip-containing bonding structures.

Referring to FIGS. 3D and 3E, a portion of a bonded assembly is illustrated in an embodiment in which the first chip-containing structure may comprise a two-dimensional array of memory elements, and the memory elements are three-terminal memory devices. In this embodiment, word lines (WL's), first bit lines (BL1's), and second bit lines (BL2's) may be used to access each of the three-terminal memory devices. In the illustrated configuration, the first bit lines and the second bit lines may be formed at different levels, and thus, are spaced from the second chip-containing structure by different vertical distances. Die-to-die connection structures for the first bit lines and die-to-die connection structures for the second bit lines are expressly illustrated in FIGS. 3D and 3E, while die-to-die connection structures for the word lines are not expressly illustrated, although such die-to-die connection structures for the word lines are present in the bonded assembly and provide electrical connection between the two chip-containing bonding structures.

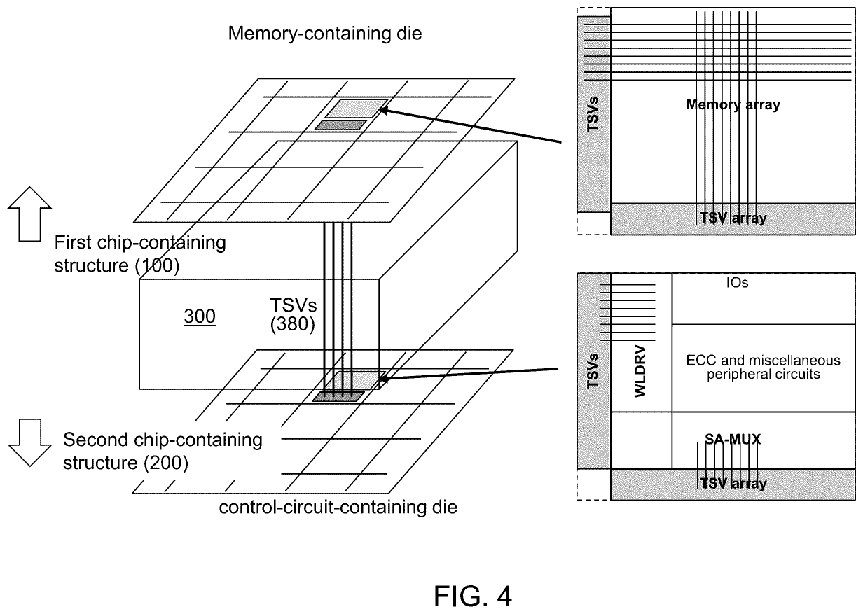

Referring to FIG. 4, an exemplary layout for through-substrate via (TSV) structures 380 is shown in embodiments in which an array of TSV structures 380 may be used as a die-to-die connection structures. In embodiments in which an array of TSV structures 380 may be used as the die-to-die connection structures, a dedicated area for forming the die-to-die connection structures may be formed outside the area of the memory array (i.e., the array area). In one embodiment, each TSV structure 380 may have a height that is greater than the lateral dimension (i.e., the maximum lateral dimension). In one embodiment, the TSV structures 380 may have a respective cylindrical shape or a respective pillar shape. While such an overhead in the area is desired, a stack of multiple BEOL memory dies may be formed without any further area penalty (i.e., without any additional device area overhead). In this embodiment, a single control circuit in the control-circuit-containing die may control a plurality of memory arrays located within the stack of multiple BEOL memory dies. In a non-limiting illustrative example, the control circuit may comprise word line drivers (WLDRV), sense amplifiers (SA), multiplexers (MUX), input-output circuitries (IOs), error correction circuitries (ECC), and miscellaneous peripheral circuits.

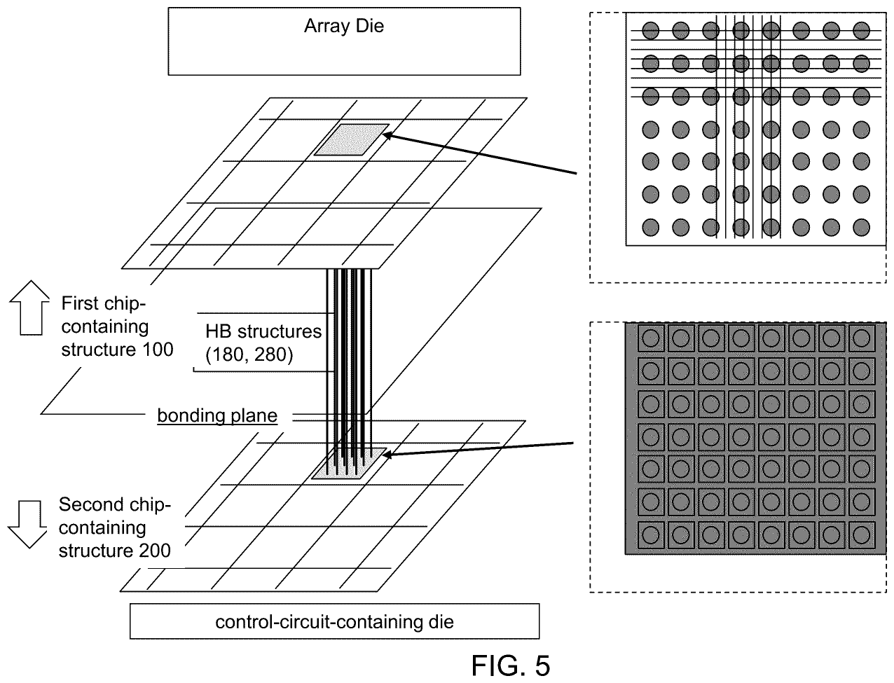

Referring to FIG. 5, an exemplary layout for bonding pad arrays is illustrated, which may be used for hybrid bonding for the chip assembly structure according to an embodiment of the present disclosure. In this embodiment, the first bonding structures 180 and the second bonding structures 280 may comprise bonding pads. In one embodiment, each of the bonding pads may have a respective lateral dimension that is greater than the height. Formation of the first bonding structures 180 and the second bonding structures 280 as bonding pads does not add any overhead to the BEOL memory die. As discussed above, dielectric-to-dielectric bonding may be used between the first chip-containing structure 100 and the second chip-containing structure 200 in conjunction with metal-to-metal bonding used between mating pairs of bonding structures (180, 280). In this embodiment, the first chip-containing structure 100 and the second chip-containing structure 200 may be bonded to each other through hybrid bonding. Hybrid bonding may provide high speed high bandwidth connection between mating pairs of chips. In one embodiment, a single BEOL memory die may be attached to the control-circuit-containing die. In one embodiment, the bonding between the first chip-containing structure 100 and the second chip-containing structure 200 may be front-to-front (F2F) bonding.

Referring collectively to FIGS. 1-5 and according to various embodiments of the present disclosure, a chip assembly structure is provided, which comprises: a first chip-containing structure 100 that comprises a back-end-of-line (BEOL) memory die including an array of memory cells and metal interconnect structures that are electrically connected to a respective node of the memory cells, wherein the BEOL memory die is free of any semiconductor material portion or each semiconductor material portions within the BEOL memory die has a lateral extent that is less than a lateral extent of each memory cell within the array of memory cells, the first chip-containing structure 100 comprises first bonding structures 180, and a subset of the first bonding structures 180 is electrically connected to the metal interconnect structures in the BEOL memory die; and a second chip-containing structure 200 that comprises a control circuit including field effect transistors which are configured to control operation of the array of memory cells and further comprises second bonding structures 280, wherein the second bonding structures 280 are bonded to the first bonding structures 180 through metal-to-metal bonding or through-substrate-via-mediated bonding.

In one embodiment, at least one set of bonding structures selected from the first bonding structures 180 and the second bonding structures 280 comprise an array of through-substrate via (TSV) structures having a respective height that is greater than a respective lateral dimension.

In one embodiment, at least one set of bonding structures selected from the first bonding structures 180 and the second bonding structures 280 comprise an array of metal bonding pads having a respective lateral dimension that is greater than a respective thickness.

In one embodiment, the first bonding structures 180 are laterally surrounded by a first bonding-level dielectric layer 160; the second bonding structures 280 are laterally surrounded by a second bonding-level dielectric layer 260; and the second bonding-level dielectric layer 260 is bonded to the first bonding-level dielectric layer 160 through dielectric-to-dielectric bonding, for example, as in the embodiment of hybrid bonding between the first chip-containing structure 100 and the second chip-containing structure 200.

In one embodiment, the first bonding structures 180 are laterally surrounded by a first bonding-level dielectric layer 160; the second bonding structures 280 are laterally surrounded by a second bonding-level dielectric layer 200; and the second bonding-level dielectric layer 200 is vertically spaced from the first bonding-level dielectric layer 160 by a gap, for example, as in the embodiment of through-substrate-via-mediated bonding between the first chip-containing structure 100 and the second chip-containing structure 200.

In one embodiment, the BEOL memory die is free of any field effect transistor. In one embodiment, the BEOL memory die is free of any semiconductor material.

Generally, the BEOL memory die is free of any FEOL components. As such, the BEOL memory die is free of any semiconductor substrate. In one embodiment, the array of memory cells and the metal interconnect structures in the BEOL memory die are laterally surrounded by a set of dielectric material layers of the BEOL memory die; and the set of dielectric material layers continuously extends from a bottom surface of the BEOL memory die to a top surface of the BEOL memory die without spacing between any neighboring pair of dielectric material layers within the set of dielectric material layers. In other words, any point on a dielectric bottom surface of the BEOL memory die may be connected to any point on a dielectric top surface of the BEOL memory die through a respective continuous path that extends only through the set of dielectric material layers.

In one embodiment, the control circuit comprises a complementary metal-oxide-semiconductor (CMOS) circuit located on a single crystalline semiconductor substrate: and additional metal interconnect structures are located between the CMOS circuit and the second bonding structures 280.

In one embodiment, the first bonding structures 180 are located within the BEOL memory die.

According to another aspect of the present disclosure, a chip assembly structure is provided, which comprises: a first chip-containing structure 100 that comprises a back-end-of-line (BEOL) memory die including an array of memory cells and metal interconnect structures that are electrically connected to a respective node of the memory cells, wherein the BEOL memory die is free of any field effect transistors, the first chip-containing structure 100 comprises first bonding structures 180, and a subset of the first bonding structures 180 is electrically connected to the metal interconnect structures in the BEOL memory die; and a second chip-containing structure 200 that comprises a control circuit including field effect transistors which are configured to control operation of the array of memory cells and further comprises second bonding structures 280, wherein the second bonding structures 280 are bonded to the first bonding structures 180 through metal-to-metal bonding or through-substrate-via-mediated bonding.

In one embodiment, the array of memory cells and the metal interconnect structures are laterally surrounded by a set of dielectric material layers; and the set of dielectric material layers continuously extends from a bottom surface of the BEOL memory die to a top surface of the BEOL memory die without spacing between any neighboring pair of dielectric material layers within the set of dielectric material layers.

Generally, the first chip-containing structure may comprise at least one additional BEOL memory die, at least one redistribution structure, at least one interposer structure, and/or at least one logic die.

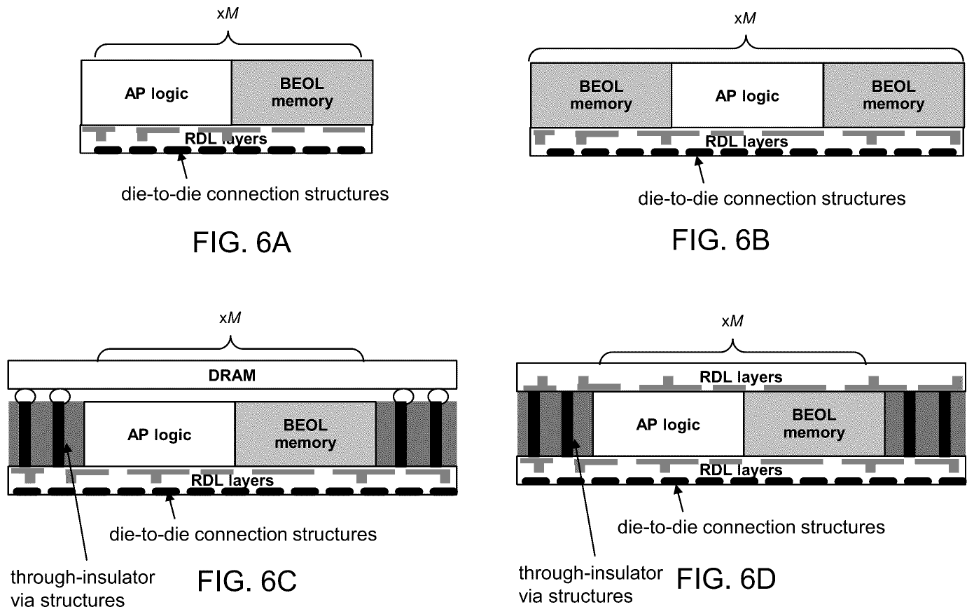

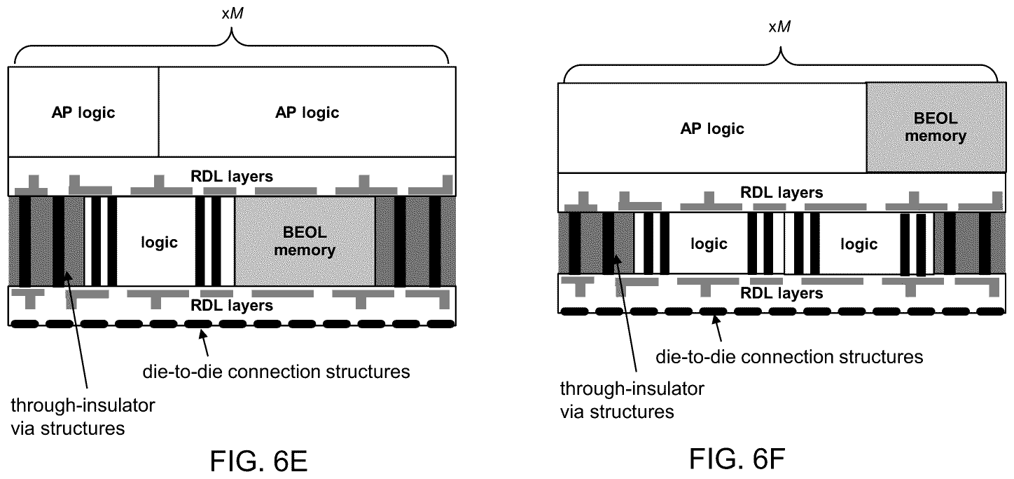

FIGS. 6A-6E illustrate various configurations for the first chip-containing structure in embodiment the first chip-containing structure comprises a redistribution structure according to an embodiment of the present disclosure.

A redistribution structure refers to a set of redistribution interconnect structures embedded within at least one redistribution dielectric layer (at least one RDL layer). Each redistribution dielectric layer may comprise a polymer material or a silicate glass (such as undoped silicate glass or a doped silicate glass). The redistribution interconnect structures may be formed by depositing and patterning a metallic material. In one embodiment, at least one semiconductor die, which may be multiple semiconductor dies, may be molded in a molding compound die frame (not expressly shown), and the redistribution structure may be formed on the combination of the molding compound die frame and the at least one semiconductor die. In this embodiment, a subset of the redistribution interconnect structures may be formed directly on metal bonding structures on the at least one semiconductor die. In another embodiment, a redistribution structure may be formed on a carrier substrate, and at least one semiconductor die, which may be multiple semiconductor dies, may be attached to the redistribution structure using at least one underfill material portion and an optional molding compound die frame.

Referring to FIG. 6A, a configuration for the first chip-containing structure is illustrated, which corresponds to an embodiment in which M instance(s) of a combination of a BEOL memory die and an application processor (AP) logic die is/are attached to a redistribution structure. The integer M is positive, i.e., may be 1, 2, 3, 4, etc. Die-to-die connection structures, such as the first bonding structures 180, may be formed on a distal side of the redistribution structure that is distal from the BEOL memory die(s). A redistribution dielectric layer may be a first bonding-level dielectric layer 160.

Referring to FIG. 6B, a configuration for the first chip-containing structure is illustrated, which corresponds to an embodiment in which M instance(s) of a combination of multiple BEOL memory dies and an application processor (AP) logic die is/are attached to a redistribution structure. The integer M is positive, i.e., may be 1, 2, 3, 4, etc. Die-to-die connection structures, such as the first bonding structures 180, may be formed on a distal side of the redistribution structure that is distal from the BEOL memory die(s). A redistribution dielectric layer may be a first bonding-level dielectric layer 160.

In some embodiments, through-insulator via (TIV) structures may be used in conjunction with a molding compound die frame to provide additional vertical signal paths.

Referring to FIG. 6C, a configuration for the first chip-containing structure is illustrated, which corresponds to an embodiment in which M instance(s) of a combination of a BEOL memory die and an application processor (AP) logic die is/are attached to a redistribution structure. The integer M is positive, i.e., may be 1, 2, 3, 4, etc. Further, TIV structures are embedded within a molding compound die frame that laterally surrounds the BEOL memory die(s) and the AP logic die(s). At least one semiconductor die may be attached to the M instance(s) of the combination of the BEOL memory die and the AP logic die, for example, using at least one array of solder material portions or using any other chip attachment method. In the illustrated example, a dynamic random access die is attached to the M instance(s) of the combination of the BEOL memory die and the AP logic die. Die-to-die connection structures, such as the first bonding structures 180, may be formed on a distal side of the redistribution structure that is distal from the BEOL memory die(s). A redistribution dielectric layer may be a first bonding-level dielectric layer 160.

Referring to FIG. 6D, a configuration for the first chip-containing structure is illustrated, which corresponds to an embodiment in which M instance(s) of a combination of a BEOL memory die and an application processor (AP) logic die are attached to a redistribution structure. The integer M is positive, i.e., may be 1, 2, 3, 4, etc. Further, TIV structures are embedded within a molding compound die frame that laterally surrounds the BEOL memory die(s) and the AP logic die(s). An additional redistribution structure may be attached to the M instance(s) of the combination of the BEOL memory die and the AP logic die, for example, by forming the additional redistribution structure directly on the M instance(s) of the combination of the BEOL memory die and the AP logic die. Die-to-die connection structures, such as the first bonding structures 180, may be formed on a distal side of the redistribution structure that is distal from the BEOL memory die(s). A redistribution dielectric layer may be a first bonding-level dielectric layer 160.

Referring to FIG. 6E, a configuration for the first chip-containing structure is illustrated, which may be derived from the configuration illustrated in FIG. 6D by attaching additional semiconductor dies to the additional redistribution structure. In the illustrated example, the additional semiconductor dies may comprise AP logic dies. A plurality of AP logic dies and additional memory dies (such as BEOL memory dies; not shown) may be attached to the additional redistribution structure.

Referring to FIG. 6F, a configuration for the first chip-containing structure is illustrated, which may be derived from the configuration illustrated in FIG. 6E by exchanging the locations of the BEOL memory die and an AP logic die.

Referring collectively to FIGS. 6A-6F, the first chip-containing structure 100 may, or may not, comprise a redistribution structure including redistribution dielectric layers and redistribution wiring interconnects; the first bonding structures 180 are located within the redistribution structure; and the BEOL memory die is located on the redistribution structure on an opposite side of the second chip-containing structure 200. In some embodiments, a subset of the metal interconnect structures within the BEOL memory die may contact a subset of the redistribution wiring interconnects.

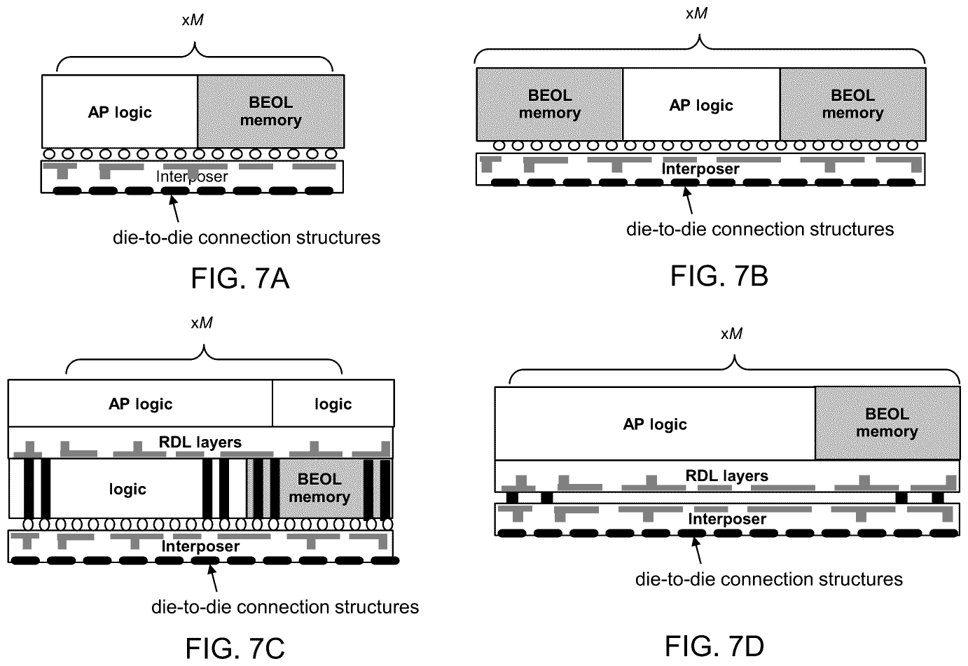

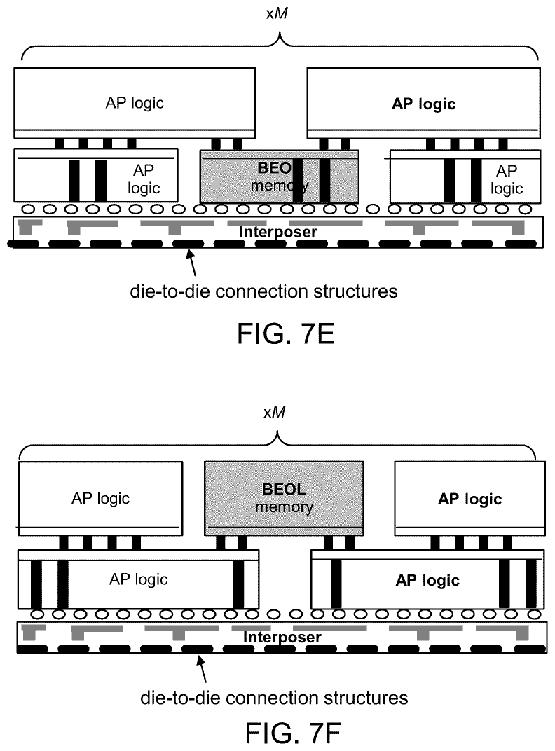

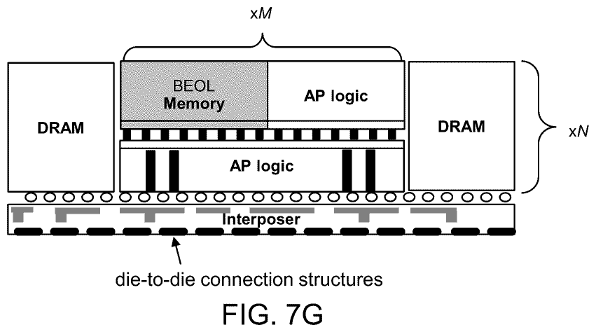

FIGS. 7A-7G illustrate various configurations for the first chip-containing structure in embodiments in which the first chip-containing structure comprises an interposer according to an embodiment of the present disclosure.

An interposer refers to a structure including a set of redistribution interconnect structures embedded within at least one redistribution dielectric layer (at least one RDL layer), and provided with at least one set of bonding structures configured for solder-bump bonding or for metal-to-metal bonding at least on one side. The interposer may comprise an organic interposer or a ceramic interposer. Each redistribution dielectric layer may comprise a polymer material or a silicate glass (such as undoped silicate glass or a doped silicate glass). The redistribution interconnect structures may be formed by depositing and patterning a metallic material. In one embodiment, at least one semiconductor die, which may be multiple semiconductor dies, may be attached to the interposer through a respective array of solder material portions (i.e., using solder bumps such as microbumps). Alternatively or additionally, at least one semiconductor die, which may be multiple semiconductor dies, may be attached to the interposer through metal-to-metal bonding or through through-substrate-via-mediated bonding.

Referring to FIG. 7A, a configuration for the first chip-containing structure is illustrated, which corresponds to an embodiment in which M instance(s) of a combination of a BEOL memory die and an application processor (AP) logic die is/are attached to an interposer. The integer M is positive, i.e., may be 1, 2, 3, 4, etc. Die-to-die connection structures, such as the first bonding structures 180, may be formed on a distal side of the interposer that is distal from the BEOL memory die(s). A redistribution dielectric layer within the interposer may be a first bonding-level dielectric layer 160.

Referring to FIG. 7B, a configuration for the first chip-containing structure is illustrated, which corresponds to an embodiment in which M instance(s) of a combination of multiple BEOL memory dies and an application processor (AP) logic die is/are attached to an interposer. The integer M is positive, i.e., may be 1, 2, 3, 4, etc. Die-to-die connection structures, such as the first bonding structures 180, may be formed on a distal side of the interposer that is distal from the BEOL memory die(s). A redistribution dielectric layer within the interposer may be a first bonding-level dielectric layer 160.

Referring to FIG. 7C, a configuration for the first chip-containing structure is illustrated, which may be derived from the configuration illustrated in FIG. 7A or 7B by forming a redistribution structure on a side of the M instance(s) of the combination of the BEOL memory die(s) and the AP logic die located on an opposite side of the interposer. In addition, additional semiconductor dies may be attached to the redistribution structure. In the illustrated example, the additional semiconductor dies may comprise M instance(s) of at least one logic die (which may include an AP logic die). In one embodiment, plurality of AP logic dies and additional memory dies (such as BEOL memory dies; not shown) may be attached to the redistribution structure. Die-to-die connection structures, such as the first bonding structures 180, may be formed on a distal side of the interposer that is distal from the BEOL memory die(s). A redistribution dielectric layer within the interposer may be a first bonding-level dielectric layer 160.

Referring to FIG. 7D, a configuration for the first chip-containing structure is illustrated, which may be derived from the structure illustrated in FIG. 6A by attaching an interposer to the structure illustrated in FIG. 6A. In this embodiment, the redistribution structure may be attached to the interposer via metal-to-metal bonding (such as hybrid bonding), or via a through-substrate-via-mediated bonding. Die-to-die connection structures, such as the first bonding structures 180, may be formed on a distal side of the interposer that is distal from the BEOL memory die(s). A redistribution dielectric layer within the interposer may be a first bonding-level dielectric layer 160.

Referring to FIG. 7E, a configuration for the first chip-containing structure is illustrated, which may be derived from the configuration illustrated in FIG. 7A by replacing the M instance(s) of a combination of a BEOL memory die and an application processor (AP) logic die with a multi-tier stack including at least one BEOL memory die and logic dies (such as AP logic dies). The at least one BEOL memory die and the logic dies may be interconnected to one another via arrays of bump structures (such as microbump structures; not shown), via metal-to-metal bonding, or via through-substrate-via-mediated bonding. A subset of the semiconductor dies within he multi-tier stack that faces the interposer may be attached to the interposer via a respective array of solder material portions (i.e., solder bumps). In one embodiment, one or more of the at least one BEOL memory die may be directly bonded to the interposer through a respective array of solder material portions, or alternatively, via metal-to-metal bonding, or via through-substrate-via-mediated bonding. Generally, M instance(s) of the multi-tier stack of semiconductor dies may be attached to the interposer, in which M is a positive integer (such as 1, 2, 3, 4, etc.).

Referring to FIG. 7F, a configuration for the first chip-containing structure is illustrated, which may be derived from the configuration illustrated in FIG. 7E by rearranging the positions of the semiconductor dies within he multi-tier stack such that at least one BEOL memory die is indirectly attached to the interposer through at least one logic die (such as at least one AP logic die). In one embodiment, one or more of the at least one BEOL memory die may be directly bonded to a respective logic die through a respective array of solder material portions, or alternatively, via metal-to-metal bonding, or via through-substrate-via-mediated bonding. Generally, M instance(s) of the multi-tier stack of semiconductor dies may be attached to the interposer, in which M is a positive integer (such as 1, 2, 3, 4, etc.).

Referring to FIG. 7G, a configuration for the first chip-containing structure is illustrated, which may be derived from the configuration illustrated in FIG. 7E or from the configuration illustrated in FIG. 7F by attaching at least one additional memory die (such as at least one dynamic random access memory die). In some embodiments, a vertical stack of N memory dies may be attached, in which N is a positive integer. In one embodiment, one or more of the at least one BEOL memory die may be directly or indirectly bonded to the interposer through a respective array of solder material portions, or alternatively, via metal-to-metal bonding, or via through-substrate-via-mediated bonding. Generally, M instance(s) of the multi-tier stack of semiconductor dies may be attached to the interposer, in which M is a positive integer (such as 1, 2, 3, 4, etc.). As discussed above, die-to-die connection structures, such as the first bonding structures 180, may be formed on a distal side of the interposer that is distal from the BEOL memory die(s). A redistribution dielectric layer within the interposer may be a first bonding-level dielectric layer 160.

Referring collectively to FIGS. 7A-7F, the first chip-containing structure 100 may comprise an interposer including redistribution dielectric layers and redistribution wiring interconnects; the first bonding structures 180 are located within the interposer; and the BEOL memory die is attached to the redistribution structure on an opposite side of the second chip-containing structure 200 via an array of solder material portions or via metal-to-metal bonding or through-substrate-via-mediated bonding.

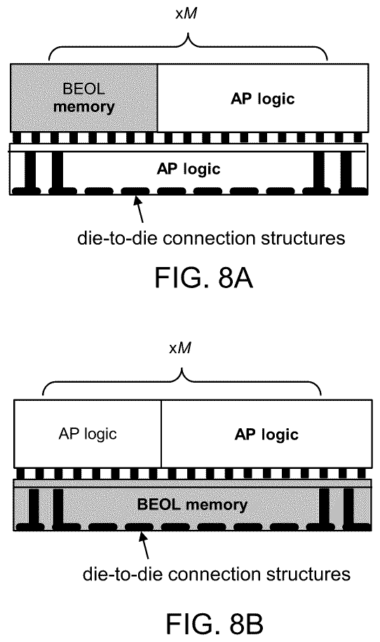

FIGS. 8A and 8B illustrate various configurations for the first chip-containing structure in embodiments in which the first chip-containing structure comprises a chip assembly that is free of redistribution structures and interposers according to an embodiment of the present disclosure.

Referring to FIG. 8A, a configuration for the first chip-containing structure is illustrated, which corresponds to an embodiment in which the first chip-containing structure comprises a vertical stack of at least one first-level semiconductor die and at least one second-level semiconductor die. Optionally, multiple instances (such as M instances) of at least one semiconductor die may be repeated along a horizontal direction as a one-dimensional array or as a two-dimensional array. Die-to-die connection structures, such as the first bonding structures 180, may be formed within the at least one first-level semiconductor die, and each of the at least one first-level semiconductor die may comprise a respective dielectric material layer that functions as a first bonding-level dielectric layer 160. In one embodiment, the at least one second-level semiconductor die may comprise at least one BEOL memory die. In one embodiment, one or more of the at least one BEOL memory die may be directly bonded to a respective logic die through a respective array of solder material portions, or alternatively, via metal-to-metal bonding, or via through-substrate-via-mediated bonding.

Referring to FIG. 8B, a configuration for the first chip-containing structure is illustrated, which may be derived from the configuration illustrated in FIG. 8A by placing at least one BEOL memory die at the first level. In other words, one or more of the at least one first-level semiconductor die comprise one or more BEOL memory die. Die-to-die connection structures, such as the first bonding structures 180, may be formed within the at least one first-level semiconductor die, and thus, within the one or more BEOL memory die. Each of the at least one first-level semiconductor die may comprise a respective dielectric material layer that functions as a first bonding-level dielectric layer 160. In one embodiment, the at least one second-level semiconductor die may comprise at least one logic die such as at least one AP logic die. In one embodiment, one or more of the at least one BEOL memory die may be subsequently directly bonded to a second chip-containing structure 200 via metal-to-metal bonding, or via through-substrate-via-mediated bonding.

Generally speaking, each BEOL memory die may comprise any type of memory device known in the art provided that such a memory device is not integrated with a field effect transistor requiring a portion of a semiconductor substrate. For example, a dynamic random access memory device including a combination of a deep trench capacitor formed within a semiconductor substrate and an access field effect transistor using a portion of the semiconductor substrate as a channel is not used as a BEOL memory device of the present disclosure.

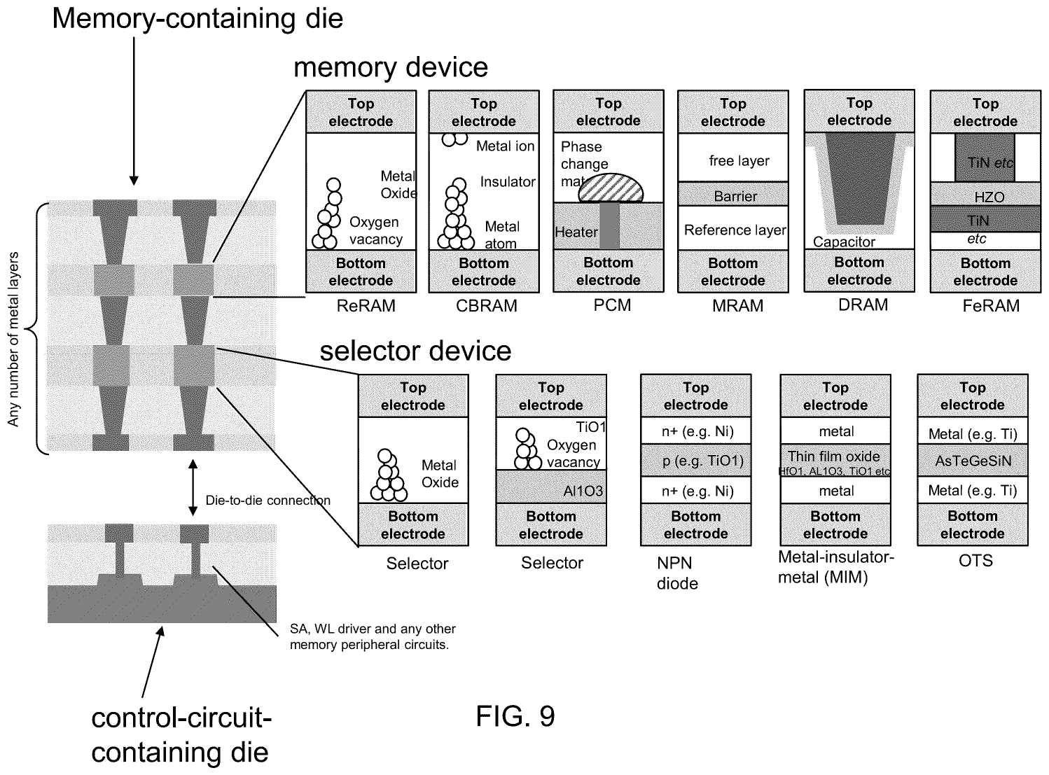

FIG. 9 is a schematic vertical cross-sectional view of a memory-containing die and a peripheral die that may be used for the chip assembly structure according to an embodiment of the present disclosure. As discussed above, any memory cell that does not require a portion of a semiconductor substrate may be used as a memory cell within the BEOL memory die of the present disclosure. As non-limiting illustrative examples, each of the memory cells in the memory array of the BEOL memory die of the present disclosure may comprise a respective memory cell that is selected from: a resistive random access memory cell; a conductive bridge random access memory cell; a phase change memory cell; a magnetoresistive random access memory cell; a dynamic random access memory cell; and a ferroelectric random access memory cell.

Further, one, a plurality, and/or each of BEOL memory die(s) within the first chip-containing structure 100 of the present disclosure may comprise an array of selector cells. In one embodiment, each of the selector cells is electrically connected to a respective memory cell within the array of memory cells; and each of the selector cells comprises a respective selector cell that is selected from: an oxygen-vacancy-based selector cell (which may, or may not, include a barrier oxide layer such as an aluminum oxide layer); a diode selector cell (such as an NPN diode cell); a metal-insulator-metal (MIM) selector cell; and an ovonic threshold switch (OTS) selector cell.

Generally, any type of selector cell that may be formed as a BEOL component may be integrated into a BEOL memory die of the present disclosure. In one embodiment, switching devices that may be manufactured as BEOL components may be integrated into a BEOL memory die of the present disclosure. Such switching devices may include thin film transistors or tunneling field effect transistors using semiconducting metal oxide material portions having lateral extents not greater than the lateral extent of each memory cell, switching devices using a two-dimensional material such as nanowires or graphenes, or any other BEOL switching devices, i.e., a switching device that may be formed at a metal interconnect level.

As discussed above, the BEOL memory die is free of any FEOL components. Thus, the BEOL memory die is free of any semiconductor substrate. In one embodiment, the array of memory cells and the metal interconnect structures in the BEOL memory die are laterally surrounded by a set of dielectric material layers of the BEOL memory die; and the set of dielectric material layers continuously extends from a bottom surface of the BEOL memory die to a top surface of the BEOL memory die without spacing between any neighboring pair of dielectric material layers within the set of dielectric material layers. In other words, any point on a dielectric bottom surface of the BEOL memory die may be connected to any point on a dielectric top surface of the BEOL memory die through a respective continuous path that extends only through the set of dielectric material layers.

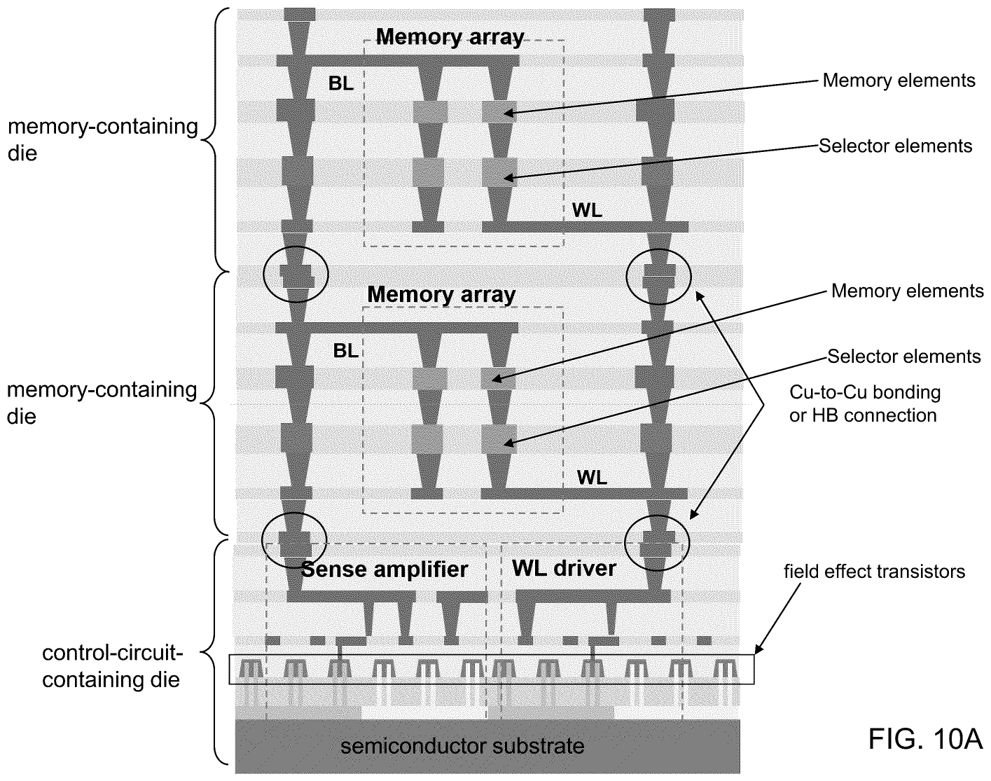

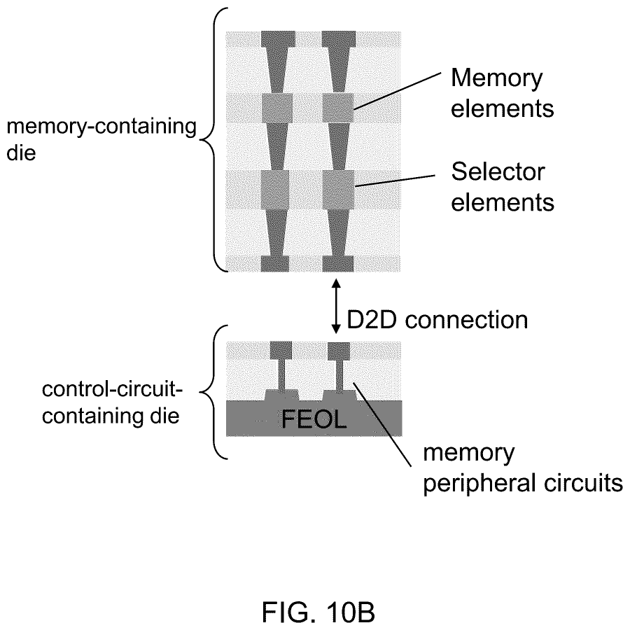

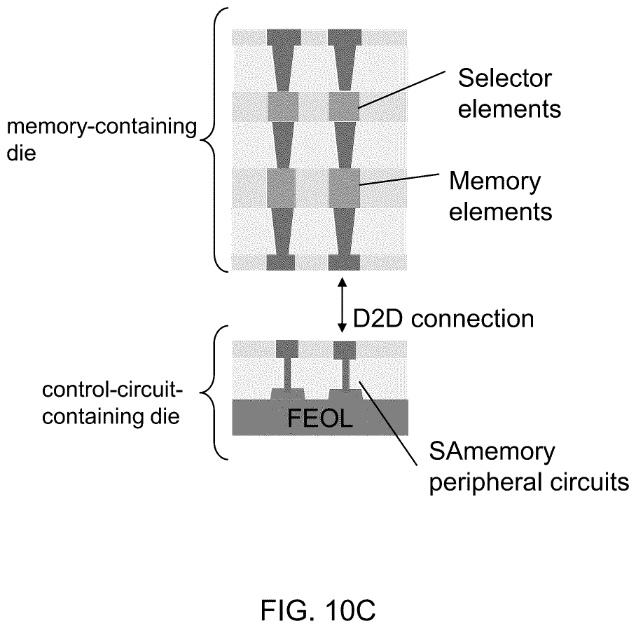

FIG. 10 is a schematic vertical cross-sectional view of a chip assembly structure including two memory-containing dies and a peripheral die according to an embodiment of the present disclosure. In this example, multiple BEOL memory dies may share a same control circuit located within a control-circuit-containing die located within a second chip-containing structure. The control-circuit-containing die and a first BEOL memory die may be connected to each other through metal-to-metal bonding or through-substrate-via-mediated bonding. The second BEOL memory die may be connected to the first BEOL memory die through metal-to-metal bonding or through-substrate-via-mediated bonding. Generally, the word line driver may, or may not, be shared with the multiple BEOL memory dies. The bit line drivers (and the sense amplifiers) may, or may not, be shared with the multiple BEOL memory dies. Each BEOL memory die may comprise a respective array of memory cells, and may optionally include a respective array of selector elements.

FIGS. 10B and 10C are schematic vertical cross-sectional view of a chip assembly structure including a memory-containing die and a peripheral die according to an embodiment of the present disclosure. In some embodiment, each memory device within a memory-containing die, such as a BEOL memory die, may include a series connection of a memory element and selector element. The memory element and the selector element may interconnected to each other through a respective metal interconnect structure such as a metal via structure or a metal pad structure. The memory element may overlie, or underlie, the selector element. In one embodiment, the memory elements may be more proximal to the control-circuit-containing die than the selector elements are to the control-circuit-containing die. In one embodiment, the selector elements may be more proximal to the control-circuit-containing die than the memory elements are to the control-circuit-containing die.

Generally, a BEOL memory die may consist of an array of memory devices such as a two-dimensional array of memory devices, metal interconnect structures and metal bonding pads electrically connected to array of memory devices, and dielectric material layers embedding the array of memory devices. The BEOL memory die may be free of any semiconductor substrate or any semiconductor material layer. The BEOL memory die may be free of any semiconductor material unless the memory devices include a semiconductor material. Thus, in embodiments in which the memory devices are free of any semiconductor material, the BEOL memory die may be free of any semiconductor material. In embodiments in which the memory devices include a semiconductor material, any such semiconductor material may be embodied as a component of the memory device, and each portion of any semiconductor material in the BEOL memory die may have a spatial extent that is less than the spatial extent of a unit memory cell.

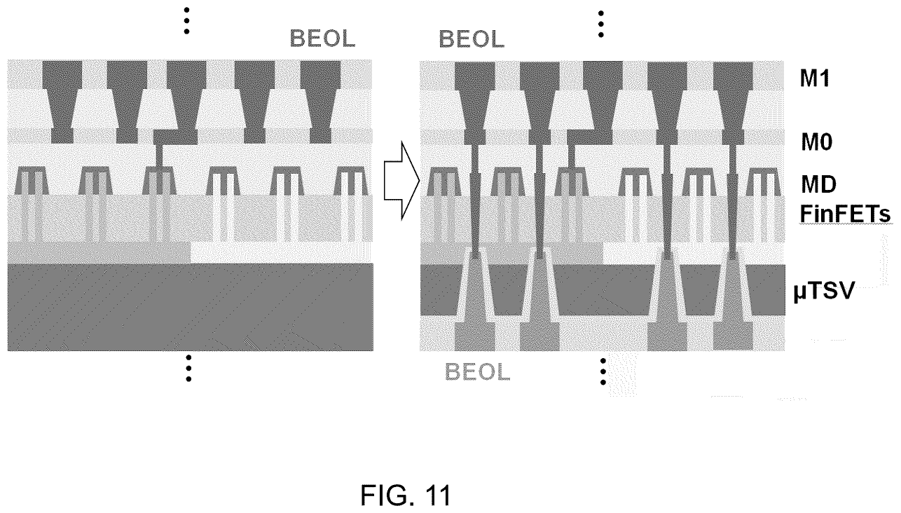

Referring to FIG. 11, backside through-substrate via structures may be optionally formed on a backside of the second chip-containing structure of the present disclosure. In this embodiment, the chip assembly structure of the present disclosure may be mounted on a packaging substrate, or on an interposer, using the backside through-substrate via structures.

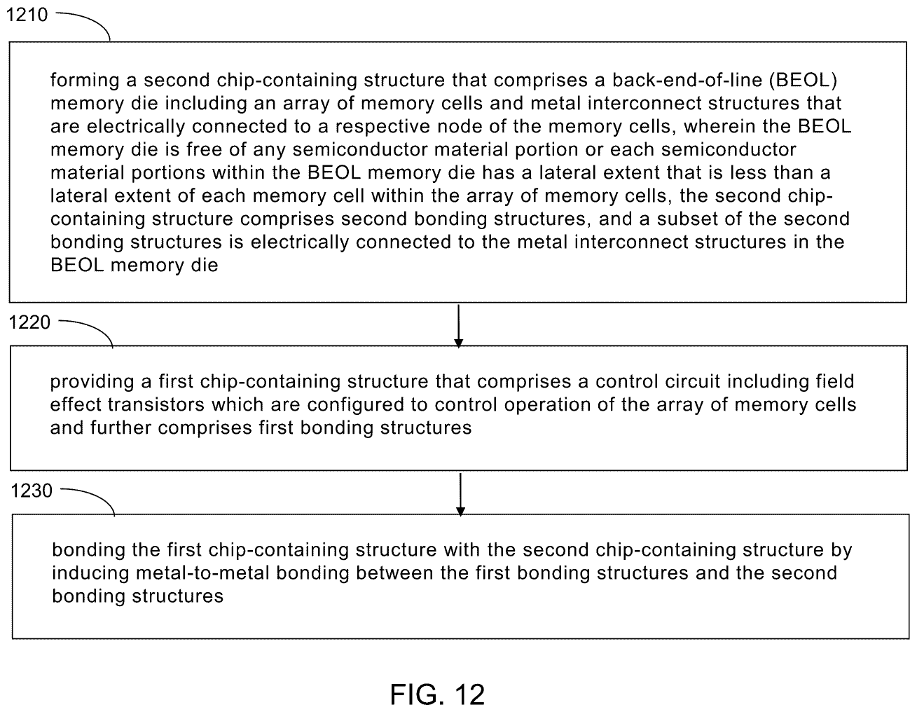

FIG. 12 is a flowchart that illustrates general processing steps for manufacturing the chip assembly structure according to an embodiment of the present disclosure.

Referring to step 1210 and FIGS. 1-10C, a first chip-containing structure 100 may be formed, which comprises a back-end-of-line (BEOL) memory die including an array of memory cells and metal interconnect structures that are electrically connected to a respective node of the memory cells. The BEOL memory die is free of any semiconductor material portion or each semiconductor material portions within the BEOL memory die has a lateral extent that is less than a lateral extent of each memory cell within the array of memory cells, the first chip-containing structure 100 comprises first bonding structures 180. A subset of the first bonding structures 180 is electrically connected to the metal interconnect structures in the BEOL memory die.

In one embodiment, the array of memory cells and the metal interconnect structures are laterally surrounded by a set of dielectric material layers; and the set of dielectric material layers continuously extends from a bottom surface of the BEOL memory die to a top surface of the BEOL memory die without spacing between any neighboring pair of dielectric material layers within the set of dielectric material layers.

In one embodiment, the BEOL memory die is free of any field effect transistor. In one embodiment, the first chip-containing structure 100 comprises a redistribution structure, an interposer, or at least another semiconductor chip overlying, underlying, or laterally surrounded by a same molding compound frame as, the BEOL memory die.

Referring to step 1220 and FIGS. 1-5 and 9-11, a second chip-containing structure 200 is provided, which comprises a control circuit including field effect transistors which are configured to control operation of the array of memory cells and further comprises second bonding structures 280.

Referring to step 1230 and FIGS. 1-11, the second chip-containing structure 200 may be bonded with the first chip-containing structure 100 by inducing metal-to-metal bonding or through-substrate-via-mediated bonding between the second bonding structures 280 and the first bonding structures 180.

Referring to all drawings and according to an aspect of the present disclosure, a chip assembly structure of the present disclosure may comprise: a first chip-containing structure 100 that comprises a back-end-of-line (BEOL) memory die including an array of memory cells and metal interconnect structures that are electrically connected to a respective node of the memory cells, wherein the BEOL memory die is free of any semiconductor material portion or each semiconductor material portions within the BEOL memory die has a lateral extent that is less than a lateral extent of each memory cell within the array of memory cells, the first chip-containing structure 100 comprises first bonding structures 180, and a subset of the first bonding structures 180 is electrically connected to the metal interconnect structures in the BEOL memory die; and a second chip-containing structure 200 that comprises a control circuit including field effect transistors which are configured to control operation of the array of memory cells and further comprises second bonding structures 280, wherein the second bonding structures 280 are bonded to the first bonding structures 180 through metal-to-metal bonding or through-substrate-via-mediated bonding.

Referring to all drawings and according to another aspect of the present disclosure, a chip assembly structure is provided, which comprises: a first chip-containing structure 100 that comprises a back-end-of-line (BEOL) memory die including an array of memory cells and metal interconnect structures that are electrically connected to a respective node of the memory cells, wherein the BEOL memory die is free of any field effect transistors, the first chip-containing structure 100 comprises first bonding structures 180, and a subset of the first bonding structures 180 is electrically connected to the metal interconnect structures in the BEOL memory die; and a second chip-containing structure 200 that comprises a control circuit including field effect transistors which are configured to control operation of the array of memory cells and further comprises second bonding structures 280, wherein the second bonding structures 280 are bonded to the first bonding structures 180 through metal-to-metal bonding or through-substrate-via-mediated bonding.

The various embodiments of the present disclosure may be used to manufacture a semiconductor device including a BEOL memory die, i.e., a memory die consisting of only BEOL components and free of FEOL components. The manufacturing process for the BEOL memory die of the present disclosure may be optimized without regard to any performance degradation of FEOL devices that are used to control operation of the memory array in the BEOL memory die. By separating all FEOL devices from the BEOL memory die, the BEOL memory die may be manufactured for optimal performance of the memory devices. The BEOL memory die may be incorporated into a first chip-containing structure, and the control circuit is provided within a control-circuit-containing die, which may be, or may be incorporated into, a second chip-containing structure. The first chip-containing structure and the second chip-containing structure may be bonded to each other through metal-to-metal bonding or through-substrate-via-mediated bonding.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A chip assembly structure comprising:
a first chip-containing structure that comprises a back-end-of-line (BEOL) memory die including an array of memory cells and metal interconnect structures that are electrically connected to a respective node of the array of memory cells, wherein the BEOL memory die is free of any semiconductor material portion or each semiconductor material portions within the BEOL memory die has a lateral extent that is less than a lateral extent of each memory cell within the array of memory cells, the first chip-containing structure comprises first bonding structures, and a subset of the first bonding structures is electrically connected to the metal interconnect structures in the BEOL memory die; and
a second chip-containing structure that comprises a control circuit including field effect transistors which are configured to control operation of the array of memory cells and further comprises second bonding structures,
wherein the second bonding structures are bonded to the first bonding structures through metal-to-metal bonding or through-substrate-via-mediated bonding.

2. The chip assembly structure of claim 1, wherein at least one set of bonding structures selected from the first bonding structures and the second bonding structures comprise an array of through-substrate via (TSV) structures having a respective height that is greater than a respective lateral dimension.

3. The chip assembly structure of claim 1, wherein at least one set of bonding structures selected from the first bonding structures and the second bonding structures comprise an array of metal bonding pads having a respective lateral dimension that is greater than a respective thickness.

4. The chip assembly structure of claim 1, wherein:
the first bonding structures are laterally surrounded by a first bonding-level dielectric layer;
the second bonding structures are laterally surrounded by a second bonding-level dielectric layer; and
the second bonding-level dielectric layer is bonded to the first bonding-level dielectric layer through dielectric-to-dielectric bonding.

5. The chip assembly structure of claim 1, wherein:
the first bonding structures are laterally surrounded by a first bonding-level dielectric layer;
the second bonding structures are laterally surrounded by a second bonding-level dielectric layer; and
the second bonding-level dielectric layer is vertically spaced from the first bonding-level dielectric layer by a gap.

6. The chip assembly structure of claim 1, wherein the BEOL memory die is free of any field effect transistor.

7. The chip assembly structure of claim 1, wherein the BEOL memory die is free of any semiconductor material.

8. The chip assembly structure of claim 1, wherein:
the array of memory cells and the metal interconnect structures are laterally surrounded by a set of dielectric material layers; and
the set of dielectric material layers continuously extends from a bottom surface of the BEOL memory die to a top surface of the BEOL memory die without spacing between any neighboring pair of dielectric material layers within the set of dielectric material layers.

9. The chip assembly structure of claim 1, wherein:
the control circuit comprises a complementary metal-oxide-semiconductor (CMOS) circuit located on a single crystalline semiconductor substrate; and
additional metal interconnect structures are located between the CMOS circuit and the second bonding structures.

10. The chip assembly structure of claim 1, wherein:
the first chip-containing structure comprises a redistribution structure including redistribution dielectric layers and redistribution wiring interconnects;
the first bonding structures are located within the redistribution structure; and
the BEOL memory die is located on the redistribution structure on an opposite side of the second chip-containing structure.

11. The chip assembly structure of claim 1, wherein:
the first chip-containing structure comprises an interposer including redistribution dielectric layers and redistribution wiring interconnects;
the first bonding structures are located within the interposer; and
the BEOL memory die is attached to the interposer on an opposite side of the second chip-containing structure via an array of solder material portions or via metal-to-metal bonding or through-substrate-via-mediated bonding.

12. The chip assembly structure of claim 1, wherein the first bonding structures are located within the BEOL memory die.

13. A chip assembly structure comprising:
a first chip-containing structure that comprises a back-end-of-line (BEOL) memory die including an array of memory cells and metal interconnect structures that are electrically connected to a respective node of the array of memory cells, wherein the BEOL memory die is free of any field effect transistors, the first chip-containing structure comprises first bonding structures, and a subset of the first bonding structures is electrically connected to the metal interconnect structures in the BEOL memory die; and
a second chip-containing structure that comprises a control circuit including field effect transistors which are configured to control operation of the array of memory cells and further comprises second bonding structures,
wherein the second bonding structures are bonded to the first bonding structures through metal-to-metal bonding or through-substrate-via-mediated bonding.

14. The chip assembly structure of claim 13, wherein each memory cell of the array of memory cells comprises a respective memory cell that is selected from:
a resistive random access memory cell;
a conductive bridge random access memory cell;
a phase change memory cell;
a magnetoresistive random access memory cell;
a dynamic random access memory cell; and
a ferroelectric random access memory cell.

15. The chip assembly structure of claim 13, wherein the BEOL memory die further comprises an array of selector cells, wherein:
each of the array of selector cells is electrically connected to a respective memory cell within the array of memory cells; and
each of the array of selector cells comprises a respective selector cell that is selected from:
an oxygen-vacancy-based selector cell;
a diode selector cell;
a metal-insulator-metal selector cell; and
an ovonic threshold switch selector cell.

16. The chip assembly structure of claim 13, wherein:
the array of memory cells and the metal interconnect structures are laterally surrounded by a set of dielectric material layers; and
the set of dielectric material layers continuously extends from a bottom surface of the BEOL memory die to a top surface of the BEOL memory die without spacing between any neighboring pair of dielectric material layers within the set of dielectric material layers.

17. A method of forming a chip assembly structure, the method comprising:
forming a first chip-containing structure that comprises a back-end-of-line (BEOL) memory die including an array of memory cells and metal interconnect structures that are electrically connected to a respective node of the array of memory cells, wherein the BEOL memory die is free of any semiconductor material portion or each semiconductor material portions within the BEOL memory die has a lateral extent that is less than a lateral extent of each memory cell within the array of memory cells, the first chip-containing structure comprises first bonding structures, and a subset of the first bonding structures is electrically connected to the metal interconnect structures in the BEOL memory die;
providing a second chip-containing structure that comprises a control circuit including field effect transistors which are configured to control operation of the array of memory cells and further comprises second bonding structures; and
bonding the second chip-containing structure with the first chip-containing structure by inducing metal-to-metal bonding or through-substrate-via-mediated bonding between the second bonding structures and the first bonding structures.

18. The method of claim 17, wherein:
the array of memory cells and the metal interconnect structures are laterally surrounded by a set of dielectric material layers; and
the set of dielectric material layers continuously extends from a bottom surface of the BEOL memory die to a top surface of the BEOL memory die without spacing between any neighboring pair of dielectric material layers within the set of dielectric material layers.

19. The method of claim 17, wherein the BEOL memory die is free of any field effect transistor.

20. The method of claim 17, wherein the first chip-containing structure comprises a redistribution structure, an interposer, or at least another semiconductor chip overlying, underlying, or laterally surrounded by a same molding compound frame as, the BEOL memory die.
